(19) United States
(12) Patent Application Publication
(10) Pub. No.: US 2015/0037122 A1
(43) Pub. Date: Feb. 5, 2015

(54) STATION ARRANGEMENT FOR PROCESSING AND/OR MEASURING SEMICONDUCTOR WAFERS, AND ALSO PROCESSING METHOD

(71) Applicant: Fraunhofer-Gesellschaft Zur Foerderung Der Angewandten Forschung E.V., Munich (DE)

(72) Inventors: Martin Schellenberger, Erlangen (DE); Dirk Lewke, Erlangen (DE)

(21) Appl. No.: 14/380,282

(22) PCT Filed: Feb. 22, 2013
(86) PCT No.: PCT/EP2013/053524

§ 371 Date: Aug. 21, 2014

(30) Foreign Application Priority Data
Feb. 24, 2012 (EP) 12156856.2

(51) Int. Cl. H01L 21/677; H01L 21/68; H01L 21/66

(52) U.S. Cl. CPC H01L 21/67703; H01L 22/10; H01L 21/67739; H01L 21/68
USPC 414/222.07; 438/14

(57) ABSTRACT

The present invention relates to a station arrangement for processing and/or measuring semiconductor wafers which comprises, as individual modules, at least one loading module, at least one process station for processing the semiconductor wafers and/or at least one measuring station for measuring a variable of the semiconductor wafers, at least one adjustment-/cooling station and also at least one transport robot which is disposed in a transport housing. The transport robot enables the transport of the semiconductor wafers to be processed between the loading module and the respective process station for processing the semiconductor wafers and/or the at least one measuring station for measuring the semiconductor wafers. The invention relates to the particular arrangement of the adjustment-/cooling station within the station arrangement so that as low a spatial requirement of the individual modules within the station arrangement as possible and hence a space-saving construction of the station arrangement results in total.

### PRIORITY INFORMATION

The present application is a 371 National Phase Application of PCT Application No. PCT/EP2013/053524, filed on Feb. 22, 2013, that claims priority to EP Application No. 12156856.2, filed on Feb. 24, 2012, both of which are incorporated herein by reference in their entireties.

### BACKGROUND OF THE INVENTION

The present invention relates to a station arrangement for processing and/or measuring semiconductor wafers which comprises, as individual modules, at least one loading module, at least one process station for processing the semiconductor wafers and/or at least one measuring station for measuring a variable of the semiconductor wafers, at least one adjustment-/cooling station and also at least one transport robot which is disposed in a transport housing. The transport robot enables the transport of the semiconductor wafers to be processed between the loading module and the respective process station for processing the semiconductor wafers and/or the at least one measuring station for measuring the semiconductor wafers. The invention relates to the particular arrangement of the adjustment-/cooling station within the station arrangement so that as low a spatial requirement of the individual modules within the station arrangement as possible and hence a space-saving construction of the station arrangement results in total.

In addition, the present invention relates to a corresponding processing method and also measuring method for semiconductor wafers.

Station arrangements for the processing of semiconductor wafers which are known from the state of the art generally comprise a loading module, one or more process stations and also a transport chamber in which a transport robot for the transport of the semiconductor wafers between the individual modules is disposed. Such station arrangements are shown for example in Munekazu Komiya, Vacuum Platform Technology for 450 mm; RORZE Corporation;

http://www.sematech.org/meetings/archives/symposia/9028/Session7_{—}450mm/Komiya_Munekazu.pdf.

Likewise, corresponding station arrangements are described in Brooks; Fabexpress Systems (FX);

http://www.brooks.com/pages/123_fabexpress_systems_fx.cfm;

### 20 Oct. 2011.

In industrial-scale manufacture, the loading module for the transport container is usually replaced by a module which can control a plurality of transport containers at the same time—a so-called equipment front-end module (EFEM). Such an EFEM is connected via buffer stations to the transport chamber and has a further (separate) handling robot. Because of its size, it offers sufficient room for adjustment- and/or cooling stations which is also used correspondingly. The use of an EFEM is only worthwhile if a high throughput is intended to be achieved. Merely for the integration of adjustment- and/or cooling stations, the costs for an EFEM are too high.

The vertical arrangement of a cooling station is known from at least one high-temperature processing device in which the cooling station is fitted above the actual process station and can be controlled by the transport robot. In this application, the cooling station however applies to the process device and is not available for other processes.

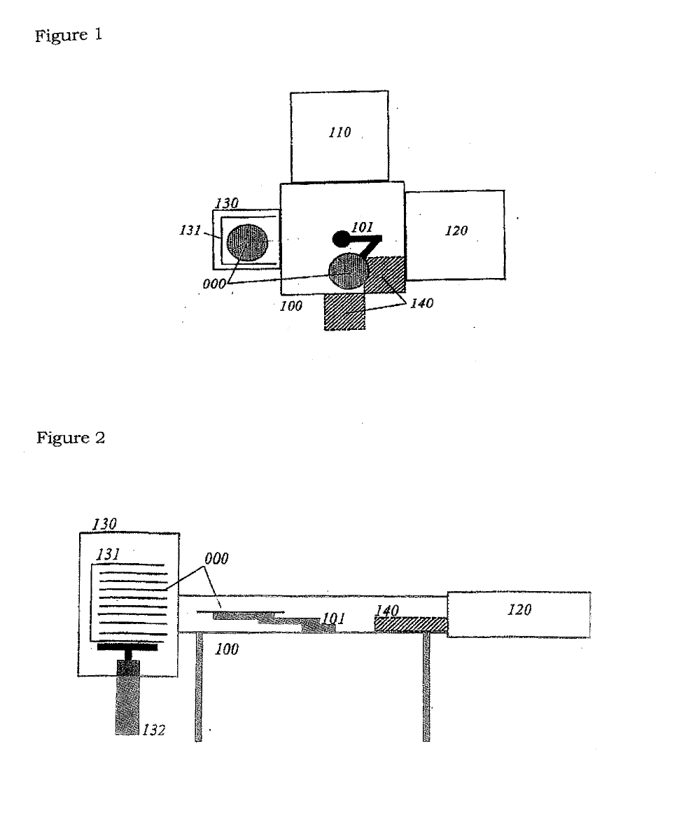

The arrangement of the individual modules corresponding to station arrangements known from the state of the art may be explained subsequently in more detail with reference to FIGS. 1 and 2.

FIG. 1 shows a station arrangement for processing semiconductor wafers as are known from the state of the art. FIG. 1 thereby shows a plan view on a corresponding station arrangement, whilst FIG. 2 illustrates a side view of the same station arrangement. The side view which is illustrated in FIG. 2 represents the direction of view onto the station arrangement of FIG. 1 from the side.

FIG. 1 shows a station arrangement for processing semiconductor wafers which comprises a loading module 130 in which the semiconductor wafers 000 can be stored. The loading module 130 is thereby configured for example such that it can receive a transport container 131 in which the semiconductor wafers 000 are sorted. As is evident from FIG. 2, the semiconductor wafers 000 can be stored stacked at corresponding positions in the transport container 131. The transport container 131 can thereby be mounted for example by means of a lift 132 to be vertically adjustable within the loading module 130 for the transport container 131. The centrepiece of the station arrangement is thereby a transport chamber 100 which comprises a robot 101. The robot 101 thereby has for example a gripping device with which a semiconductor wafer 000 can be removed from the transport container 131 and supplied to the further modules of the station arrangement. The loading module 130 for the transport container or the transport container 131 are thereby flanged directly onto the transport chamber 100 and are in functional connection with the transport chamber, i.e. between transport chamber 100 and the loading module 130 for the transport container 131 or the transport container 131, a correspondingly large opening is present or can be made possible which enables guidance of a semiconductor wafer 000 by means of the robot 101.

In the case of the example of FIG. 1, the transport chamber 100 has a square basic plan, the loading module 130 for the transport container 131 being disposed on one side of the transport chamber 100. On two further sides of the transport chamber 100, two process stations 110 and 120 are disposed; these process stations serve for corresponding processing steps for the semiconductor wafers 000. In the process stations 110 and 120, for example tempering, oxidising, doping and/or impingement with etching gases, mechanical machining etc. can be undertaken on the semiconductor wafers 000.

Instead of the process stations 110, 120, also two measuring stations 110, 120 or respectively one process station 110, 120 and one measuring station 110, 120 can be disposed on the two further sides of the transport chamber 100 (for a better overview, the process stations and the measuring stations are provided with the same reference numbers in the Figures). In the measuring stations 110, 120, different measuring variables of the semiconductor wafers 000 can be measured.

Before supplying the semiconductor wafers 000 into the process stations and/or the measuring stations 110 and/or 120, it is possibly necessary to align or to adjust the semiconductor wafers 000. Likewise, it can be necessary again to adjust and/or to cool the semiconductor wafers 000 which are removed by means of the robot 101 out of the process stations after processing and/or out of the measuring stations 110 or 120 after measuring. For these purposes, the station arrangement according to FIG. 1 or FIG. 2 has an adjustment-/cooling station 140 with which the semiconductor wafers 000 can be aligned and/or cooled. The adjustment-/cooling station can have corresponding mechanical means for alignment or for adjustment of the semiconductor wafers 000, with which the semiconductor wafers 000 can for example be rotated. Likewise, the adjustment-/cooling station can have means with which cooling of the semiconductor wafers 000 which were tempered for example in the process stations 110 and/or 120 is made possible. The adjustment-/cooling station can thereby take over one of the previously mentioned functions, i.e. adjustment or cooling or both functions, i.e. adjustment and cooling of the semiconductor wafers 000.

According to the station arrangement known from the state of the art, the adjustment-/cooling station 140 is disposed either on a free side of the transport chamber 100 (i.e. on the side which is not covered by a loading module 130 for the transport container 131 or process stations and/or measuring stations 110 or 120); a further arrangement of the adjustment-/cooling station 140 which is known from the state of the art is thereby situated within the transport chamber 100.

When positioning the adjustment-/cooling station 140 on a free side of the transport chamber, as is illustrated for example in FIGS. 1 and 2, valuable space is lost which could otherwise be used for a further process station and/or measuring station.

When positioning the adjustment-/cooling station 140 within the transport chamber 100, as is illustrated for example in FIGS. 1 and 2, and hence in the direct handling region of the transport robot 100, the transport chamber 100 must be enlarged beyond the actual space requirement of the transport robot 101. This problem occurs in particular when large semiconductor wafer sizes, i.e. semiconductor wafers with a large diameter, for example over 200 mm, in particular over 300 mm or over 450 mm diameter, are intended to be processed. The arrangement of the adjustment-/cooling station 140 within the transport chamber 100 is hence practicable only up to a certain semiconductor wafer size, since otherwise the transport chamber 100 requires to have an unnecessarily large construction.

The processes frequently take place not at atmospheric pressure but in a vacuum. Correspondingly, the transport robot and the transport container are then encapsulated in respectively separate chambers in order to be able to adapt the pressure respectively corresponding to requirements. As a result, the space problem is exacerbated even more since, for example with accommodation of the stations in the transport chamber, this must be enlarged.

If the arrangement described here is used in a clean room, such as is used normally in semiconductor production, then the problem is exacerbated since the clean room area is extremely expensive.

### SUMMARY OF THE INVENTION

It is hence the object of the present invention to indicate a station arrangement for processing semiconductor wafers which has as space-saving a construction as possible. In addition, it is the object of the present invention to indicate a processing method and also a measuring method for semiconductor wafers which enables as efficient a method control as possible.

This object is achieved, with respect to the station arrangement, by the features of patent claim 1, with respect to a processing method for semiconductor wafers, by the features of patent claim 10 and also, with respect to a measuring method for semiconductor wafers, by the features of patent claim 12, the respective dependent patent claims representing advantageous developments.

According to the invention, a station arrangement for processing semiconductor wafers is hence provided, the station arrangement having the following modules as minimum components:
a) at least one loading module for storing semiconductor wafers,
b) at least one process station for processing the semiconductor wafers and/or at least one measuring station for measuring the semiconductor wafers,
c) at least one adjustment-/cooling station and
d) at least one transport robot which is disposed in a transport chamber and enables transport of the semiconductor wafers between the at least one loading module, the at least one process station and/or the at least one measuring station and the at least one adjustment-/cooling station.

The station arrangement according to the invention is distinguished by the at least one loading module, the at least one process station and/or the at least one measuring station, the at least one adjustment-/cooling station and the transport chamber being disposed spatially relative to each other such that

the projection of the transport path of the semiconductor wafer, which is transported by means of the transport robot from the at least one loading module into an adjustment-/cooling station, onto a transport plane, and/or the projection of the transport path of the semiconductor, which is transported by means of the transport robot from an adjustment-/cooling station into the at least one measuring station, onto a transport plane can respectively describe a closed path,
and/or
the projection of the transport path of the semiconductor wafer, which is transported by means of the transport robot from the at least one loading module via an adjustment-/cooling station into the transport chamber, onto a transport plane, and/or the projection of the transport path of the semiconductor wafer, which is transported by means of the transport robot from the transport chamber via an adjustment-/cooling station into the at least one process station and/or the at least one measuring station, onto a transport plane can respectively describe a direct path.

The previously described arrangement of the individual modules of the station arrangement hence enables an extremely advantageous space-saving arrangement of the individual modules to form the total station arrangement.

It is evident that the described space problem is hence permanently resolved:
the transport chamber must provide sufficient movement clearance with its dimensions only for the transport robot.
the space around the transport chamber is available exclusively for productive process stations or measuring stations.

In the station arrangement according to the invention, at least one of the above-mentioned conditions is hence achieved, namely:
a semiconductor wafer can be transported on a closed path from a transport container into an adjustment-/cooling station,
a semiconductor wafer can be transported on a closed path from an adjustment-/cooling station into a measuring station,
a semiconductor wafer can be transported on a direct path from a transport container via an adjustment-/cooling station into the transport housing, and/or
a semiconductor wafer can be transported on a direct path from the transport housing via an adjustment-/cooling station into at least one process station or one measuring station.

The previously described directions of the transport path of the semiconductor wafer can thereby also be reversed, the direction of movement of the semiconductor wafer serves merely for definition of the covered path of the semiconductor wafer and hence of the arrangements of the individual modules necessarily resulting herefrom.

According to the invention, there is understood by the projection of the transport path onto a transport plane of the semiconductor wafer, the trajectory of the semiconductor wafer which is covered during transport from the transport container into the respective process stations or the adjustment-/cooling stations. The transport plane thereby corresponds to the plane which results in plan view on the station arrangement. A corresponding plan view is illustrated for example in FIG. 1, the view hence represents the transport plane.

There is understood, according to the invention, by a closed path which is produced upon projection of the transport path of the semiconductor wafer to be processed and/or to be measured onto the transport plane, a path, the initial and end point of which, in projection onto the transport plane, substantially coincide or completely coincide. In the case of complete coincidence, the semiconductor wafer comes hence to rest in projection, congruently at precisely the same place at which it was previously removed. There is thereby understood by substantially coinciding that the two positions of the semiconductor wafers at the initial and end state in projection onto the transport plane still have an overlap at least in regions. According to this embodiment of the present invention, it is hence possible to transport the semiconductor wafer to be processed and/or to be measured between transport container and adjustment-/cooling station and/or between adjustment-/cooling station and one of the measuring stations on the previously mentioned closed path, i.e. the corresponding modules of the station arrangement have a corresponding spatial relation to each other. A preferred embodiment provides that the transport chamber is passed through on the closed path.

According to the invention, there is understood by a direct path which results upon projection of the transport path of the semiconductor wafer to be processed and/or to be measured onto the transport plane during transport of the semiconductor wafer from the transport container via the adjustment-/cooling station into the transport housing and/or from the loading module via an adjustment-/cooling station into a process station and/or a measuring station, a trajectory which enables direct transport between the previously mentioned modules without a fairly large change in direction of the transport direction when passing through the adjustment-/cooling station. The change in transport direction thereby is hereby less than 10°, for further preference less than 5°. In particular the semiconductor wafer to be processed during transport on a direct path moves linearly or substantially linearly between initial and end point without greater changes in direction or movements on a circular or oval trajectory being provided.

The features of the arrangement of the individual modules, which are essential to the invention, so that the previously mentioned guidance away of the semiconductor wafers become possible are not known from the state of the art, this is illustrated subsequently once again with reference to the embodiments of FIG. 1 which outlines the station arrangement according to the state of the art. In the case where a semiconductor wafer 000 is intended to be removed from the transport container 131 by means of the robot 101 and adjusted in an adjustment-/cooling station 140, firstly before processing in a process station, or before measurement in a measuring station 110 or 120, a semiconductor wafer 000 is removed by means of the robot 101 from the transport container 131 which is disposed within the loading module 130 and supplied to the adjustment-/cooling station 140. Both in the case where the adjustment-/cooling station is disposed within the transport chamber 100 or on a side of the transport chamber 100, the guidance away of the semiconductor wafer 000 is effected such that, after depositing the semiconductor wafer 000 on the adjustment-/cooling station, the latter is removed again from the adjustment-/cooling station 140 with a change in direction in the trajectory of the semiconductor wafer 000 and must be supplied to the process stations or to the measuring stations 110 and 120. The guidance away is hence disadvantageous, likewise valuable space is lost, since the station arrangement must be designed to be correspondingly large. The same is the case if the semiconductor wafer 000, after processing in the process stations or after measuring in the measuring stations 110 or 120, must be supplied again to the adjustment-/cooling station 140, for example for cooling, and subsequently is intended to be stowed again in the transport container 131. In each case, the guidance, i.e. the trajectory or the path which the semiconductor wafer 000 covers upon projection onto the transport plane (see definition above) follows such that, when transferring the semiconductor wafer 000 from the transport container 131 into the adjustment-/cooling station or from the adjustment-/cooling station 140 into the transport container 131, it does not represent a closed path (as understood according to the invention), i.e. the initial and the end point of the projected trajectory coincide.

Direct guidance away of the semiconductor wafer 000 to be processed or to be measured is just as little possible when passing through the adjustment-/cooling station upon transfer of a semiconductor wafer 000 from the transport container 131 into the respective process stations or measuring stations 110 or 120 since, upon introducing the semiconductor wafer 000 into the adjustment-/cooling station 140 and removal again herefrom, a complete change of direction (i.e. with direction reversal, 180°) (upon introduction and subsequent guidance of the semiconductor wafer 000 into or out of the adjustment-/cooling station) must always be effected. However, this leads to the station arrangements of the state of the art turning out to be extremely voluminous. The station arrangement according to the invention, as described above, hence enables an extremely compact arrangement of the modules within the station arrangement and in addition a simple method guidance during transfer of the individual semiconductor wafers into the respective modules of the station arrangement.

For the processing of semiconductor wafers, these must be removed from a transport container, adjusted and moved into one or a plurality, in succession, of process station(s) or measuring station(s). After processing or measuring, the transport back into the transport container is effected; according to the respective implemented process or implemented measurement, an intermediate step for cooling the semiconductor wafers is necessary.

These steps are effected in the production environment and frequently also in the field of research and development automatically with the help of one or more robots for removal and transfer of the semiconductor wafers, and also in an adjustment station for adjusting the semiconductor wafers and a cooling station for cooling the semiconductor wafers:
The transport container contains one or more semiconductor wafers which are disposed for example one above the other. The choice of a semiconductor wafer is effected by vertical movement either of the robot or of a mechanical lift on which the transport container is mounted.
At the adjustment station, the semiconductor wafers are adjusted, for example centrally. In addition or alternatively hereto, the semiconductor wafer can be aligned by rotation such that the marking applied on each semiconductor wafer (e.g. notch, flat or structures on the semiconductor wafer) is aligned unequivocally. As a result of this adjustment, it is ensured that each semiconductor wafer can be brought into the wafer receiving means of the process station or of the measuring station with correct positioning and alignment.
The semiconductor wafers are cooled at the cooling station. After the semiconductor wafer has reached a fixed temperature, further transport is effected.
Adjustment- and cooling station can be integrated so that a combined station performs both functions.

A preferred embodiment of the present invention provides that at least one loading module is connected in the transport plane to the transport chamber so that a semiconductor wafer which is to be processed or to be measured can be transported from the loading module via the connection by means of the transport robot into the transport chamber. In this case, the adjustment-/cooling station can be integrated at a different place in the station arrangement in order that the above-described arrangement of the individual modules relative to each other is produced. This can be for example by arrangement of the adjustment-/cooling station between the transport chamber and a process station and/or measuring station, this embodiment is dealt with subsequently in more detail.

Alternatively hereto, it is possible and preferred that an adjustment-/cooling station is disposed between at least one loading module and the transport chamber connecting the at least one loading module and the transport chamber in the transport direction so that a semiconductor wafer which is to be processed can be transported from the loading module through the adjustment-/cooling station by means of the transport robot into the transport chamber.

A further preferred embodiment of the present invention which can be present in combination with the previously mentioned preferred embodiments but also alternatively hereto is given if the transport chamber is connected in the transport plane to at least one process station and/or at least one measuring station so that a semiconductor wafer to be processed or to be measured can be transported from the transport chamber via the connection by means of the transport robot into the at least one process station and/or into the at least one measuring station. In this case, the adjustment-/cooling station can be integrated at a different place in the station arrangement in order that the above-described arrangement of the individual modules relative to each other is produced. This can be for example by arrangement of the adjustment-/cooling station between the loading module and the transport chamber, as described above.

Alternatively hereto, it is likewise possible that an adjustment-/cooling station is disposed between the transport chamber and at least one process station connecting the transport chamber and the at least one process station in the transport direction so that a semiconductor wafer to be measured can be transported from the transport chamber through the adjustment-/cooling station by means of the transport robot into the at least one measuring station.

Additionally or alternatively to the above-described embodiment, it is likewise possible that an adjustment-/cooling station is disposed between the transport chamber and at least one process station connecting the transport chamber and the at least one process station in the transport direction so that a semiconductor wafer to be measured can be transported from the transport chamber through the adjustment-/cooling station by means of the transport robot into the at least one measuring station of the transport robot into the at least one process station.

The previously described preferred embodiments, in which the adjustment-/cooling station is disposed between the loading module and the transport chamber and/or between the transport housing and at least one process station or the at least one measuring station, enables a direct transport path of a semiconductor wafer between the respective modules which are connected to each other through the adjustment-/cooling station. In the case of these embodiments, a semiconductor wafer can be transferred into the transport chamber by means of the robot arm, for example out of a transport container of a loading module, the adjustment-/cooling station is passed through, in the case of this transport, on a direct path, the semiconductor wafer can hereby be deposited for example on a cooling device of the adjustment-/cooling station and be cooled, the cooling device can be a metal block configured for example as corresponding to the outline of the semiconductor wafer. In addition or alternatively hereto, the adjustment-/cooling station can likewise have mechanical means for alignment of the semiconductor wafer on which means the semiconductor wafer can be deposited by means of the robot arm. The transport between transport chamber and the respective process station or measuring station can possibly be designed analogously if an adjustment-/cooling station is disposed between transport chamber and process station or measuring station. The transport can also be effected of course in the opposite direction, i.e. from process station or measuring station via adjustment-/cooling station into the transport chamber or from transport chamber via an adjustment-/cooling station into a loading module on a direct path.

In particular, it is preferred in the case of the station arrangement according to the invention if the at least one adjustment-/cooling station is disposed outside the transport chamber.

In one embodiment of the station arrangement according to the invention in the case of which the adjustment-/cooling station is disposed for example between loading module and transport chamber and/or between transport chamber and a process station or a measuring station, it can be provided that the adjustment-/cooling station is in fact correspondingly dimensioned such that a semiconductor wafer can be guided completely through it in width, however is shortened with respect to its length so that for example, when removing a semiconductor wafer from the loading module and when guiding through or depositing the semiconductor wafer on the adjustment-/cooling station before transfer into the transport chamber, it cannot be accommodated completely in the adjustment-/cooling station with respect to its length. In this case it is advantageous in particular if the length of the adjustment-/cooling station has 0.2 to 0.95 times, in particular 0.2 to 0.5 times, the length of a semiconductor wafer which is inserted, the semiconductor wafer being able to protrude into adjacent modules. As a result, the space requirement is reduced in addition.

A further preferred embodiment which can be provided likewise alternatively or additionally to the above-mentioned embodiments provides that at least one adjustment-/cooling station together with a loading module or a transport container of a loading module and/or with a measuring station forms a stack which is configured substantially perpendicular or perpendicular to the transport plane.

The previously described embodiments enable a closed path for transport between loading module and adjustment-/cooling station or between adjustment-/cooling station and measuring station. A corresponding transfer of a semiconductor wafer for example from a loading module into an adjustment-/cooling station which in this case with the loading module or the transport container of the loading module forms a stack is thereby effected such that a semiconductor wafer is removed from the transport container of the loading module by means of the robot and is offset relative hereto, i.e. offset perpendicular to the transport plane, is transferred into the adjustment-/cooling station so that, in projection onto the transport plane, the initial and the end point of the semiconductor wafer coincide in this case. The relative offset perpendicular to the transport plane of the semiconductor wafer can thereby be effected by relative movement of the stack and/or of the robot arm perpendicular to the transport plane, for example the stack which is formed from transport container and adjustment-/cooling station can be displaced by a mechanism perpendicular to the transport plane or the robot arm can be configured correspondingly moveably perpendicular to the transport plane. In the same way, transfer of the semiconductor wafer between adjustment/-cooling station and measuring station can be effected in the case where the adjustment-/cooling station with the measuring station forms a stack.

A preferred embodiment hereto provides that at least one adjustment-/cooling station together with a loading module or a transport container of a loading module forms a stack, the adjustment-/cooling station being configured at the upper and/or lower end and/or in the interior of the stack.

Likewise, it is possible that the station arrangement comprises at least two adjustment-/cooling stations, at least one adjustment/-cooling station together with a process station forming a stack, and this adjustment/-cooling station being configured at the upper and/or lower end of the stack.

In the case of the previously described stack construction, the translation is effected preferably perpendicular to the transport plane such that the stack is mounted statically and the transport robot comprises a movement component extending perpendicular to the transport plane and/or the stack is mounted moveably perpendicular to the transport plane. The stack can have for example a lift or a transport mechanism with which the stack can be displaced or offset perpendicular to the transport plane.

In a further preferred embodiment, the individual modules of the station arrangement, i.e. the at least one loading module, the at least one process station and/or the at least one measuring station, the at least one adjustment-/cooling station and/or the transport chamber are configured respectively to be hermetically sealable from the other modules so that the air pressure can be adjusted respectively differently. The transport container of the loading module can thereby be mounted for example in the loading module. In this case, the loading module can be sealed hermetically relative to the transport chamber. In addition, the transport container can be introduced into the loading module or be removed therefrom.

The present invention likewise relates to a processing method for semiconductor wafers, in the case of which a semiconductor wafer stored in a loading module for storing semiconductor wafers or a semiconductor wafer located in a measuring station after a measurement is removed by means of a transport robot, supplied to at least one process station for processing the semiconductor wafers, processed in the at least one process station, subsequently removed from the process station and returned into a loading module or is guided into a measuring station for measuring a measuring variable of the semiconductor wafer, the semiconductor wafer, after removal from the loading module or from the measuring station and before supply into the at least one process station and/or after removal from the at least one process station and before return into a loading module or guidance into a measuring station, being transported by means of the transport robot through at least one adjustment-/cooling station and being adjusted there and/or cooled.

The method according to the invention is distinguished by the fact that the projection of the transport path of the semiconductor wafer, which is transported by means of the transport robot from at least one loading module or from a measuring station into an adjustment-/cooling station, onto a transport plane describes respectively a closed path, and/or by the fact that the projection of the transport path of the semiconductor wafer, which is transported by means of the transport robot from the at least one loading module or from a measuring station via an adjustment/-cooling station into the transport chamber, onto a transport plane, and/or the projection of the transport path of the semiconductor wafer, which is transported by means of the transport robot from the transport chamber via an adjustment/-cooling station into the at least one process station, onto a transport plane describes respectively a direct path.

The processing method according to the invention is hence based likewise on the above-explained principles. The processing method according to the invention is likewise achieved when the reverse transport paths are run through instead of the explicitly above-indicated transport paths, i.e. when the projection of the transport path of the semiconductor wafer, which is transported by means of the transport robot from at least one adjustment/-cooling station into a transport container or a measuring station, onto a transport plane and/or the projection of the transport path of the semiconductor wafer, which is transported by means of the transport robot from at least one process station into an adjustment-/cooling station, onto a transport plane describes respectively a closed path

and/or
the projection of the transport path of the semiconductor wafer, which is transported by means of the transport robot from the transport chamber via an adjustment-/cooling station into at least one transport container or a measuring station, onto a transport plane and/or the projection of the transport path of the semiconductor wafer, which is transported by means of the transport robot from at least one process station via an adjustment/-cooling station into a transport chamber, onto a transport plane describes respectively a direct path.

The processing method according to the invention hence enables as space-saving a movement as possible of the transport path of the semiconductor wafer by means of the robot arm, at the same time as efficient a method guidance as possible in which in part a plurality of operating steps can be performed on a single transport path is ensured.

A preferred embodiment of the method provides that the processing of the semiconductor wafers 000 in the at least one process station 110, 120 comprises tempering, oxidising, sputtering, coating, etching, surface structuring and/or combinations hereof.

In addition, the present invention relates to a measuring method for semiconductor wafers in which a semiconductor wafer stored in a loading module for storing semiconductor wafers is removed by means of a transport robot, supplied to at least one measuring station for measuring at least one measuring variable of the semiconductor wafers, at least one measuring variable of the semiconductor wafers is measured in the at least one measuring station, subsequently the semiconductor wafer is removed from the measuring station and returned into a loading module, the semiconductor wafer, after removal from the loading module and before supply into the at least one measuring station and/or after removal from the at least one measuring station and before return into a loading module by means of the transport robot, being transported through at least one adjustment-/cooling station and being adjusted there and/or cooled.

The measuring method according to the invention is distinguished by the fact that the projection of the transport path of the semiconductor wafer, which is transported by means of the transport robot from the at least one loading module into an adjustment-/cooling station, onto a transport plane and/or the projection of the transport path of the semiconductor wafer, which is transported by means of the transport robot from an adjustment-/cooling station into the at least one measuring station, onto a transport plane describes respectively a closed path, and/or the projection of the transport path of the semiconductor wafer, which is transported by means of the transport robot from at least one loading module via an adjustment-/cooling station into the transport chamber, onto a transport plane and/or the projection of the transport path of the semiconductor wafer, which is transported by means of the transport robot from the transport chamber via an adjustment-/cooling station into the at least one measuring station, onto a transport plane describes respectively a direct path.

The measuring method according to the invention is hence based likewise on the above-described principles for the processing method according to the invention, only that instead of a processing step a measuring step is implemented. Processing- and measuring methods can also be combined with each other so that the processing method comprises one or more measuring step(s) and/or the measuring method comprises one or more processing step(s).

In the case of the measuring step, at least one physical measuring variable of the semiconductor wafers to be measured is thereby measured. This can hereby concern for example measuring the surface structuring of the semiconductor wafers, measuring layer thicknesses applied on the surface of these semiconductor wafers or compositions of the semiconductor wafers. For the corresponding measurements, optical or even mechanical measuring methods can be used.

The semiconductor wafers which can be used for the methods according to the invention can thereby be substantially or completely round, circular or oval but can also be n-angled, with 3≦n≦10, in particular have a rectangular, square or hexagonal configuration, have a maximum dimensioning (diameter) of at least 100 mm, preferably at least 200 mm, in particular at least 300 mm to 500 mm, particularly preferred 450 mm.

In addition, the semiconductor wafers can be pre-processed. Pre-processed semiconductor wafers thereby already comprise certain structures applied on the semiconductor wafers, such as for example structured circuits, mechanical components etc.

In addition, it is possible that, in the processing method according to the invention, at least the processing step is implemented in the at least one process station at reduced pressure relative to normal conditions.

The methods according to the invention are implemented advantageously with a previously described station arrangement.

In the case of a combined method control, the semiconductor wafers being both processed and measured, also a combined process station is conceivable which has both at least one process station and one measuring station.

This solution route is used in all devices in which a transport robot receives a semiconductor wafer at one position and deposits it at another and, in between, alignment and/or cooling of the semiconductor wafer must take place. Receiving- and depositing positions can be process devices, intermediate stations or transport containers, such as e.g. standard mechanical interface (SMIF) (SEMI standard E19-1105), Front open unified pad (FOUP) or a cassette.

### DETAILED DESCRIPTION OF THE ILLUSTRATED EMBODIMENTS

The present invention is described in more detail with reference to the subsequent Figures without restricting the invention to the illustrated embodiments.

There are thereby shown

FIG. 1 shows a station arrangement for processing semiconductor wafers

FIG. 2 represents the direction of view onto the station arrangement of FIG. 1 from the side.

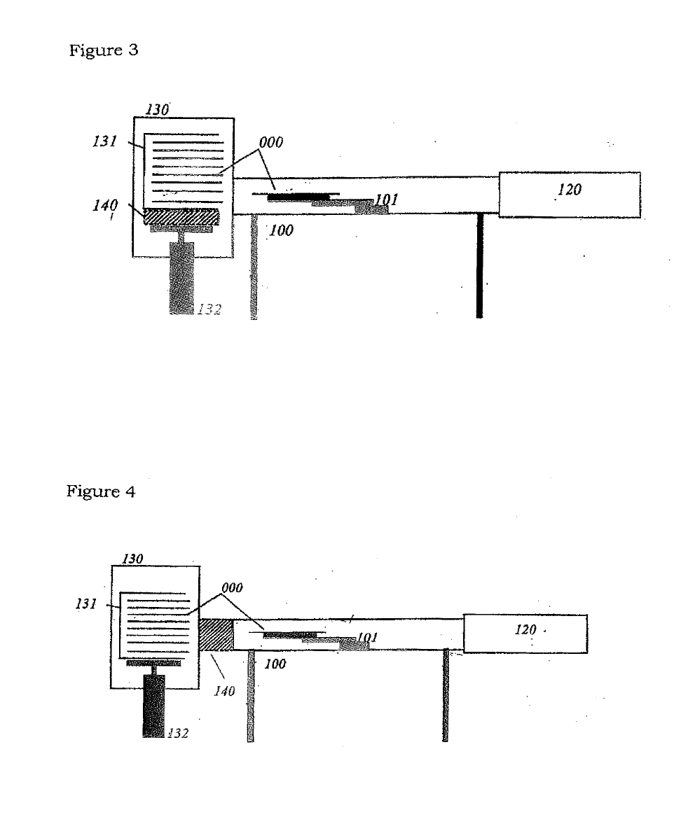

FIG. 3 a station arrangement according to the invention in side view in which the adjustment-/cooling station is produced in stack construction with the transport container and

FIG. 4 a station arrangement according to the invention in which the adjustment-/cooling station is disposed between transport container and transport chamber and

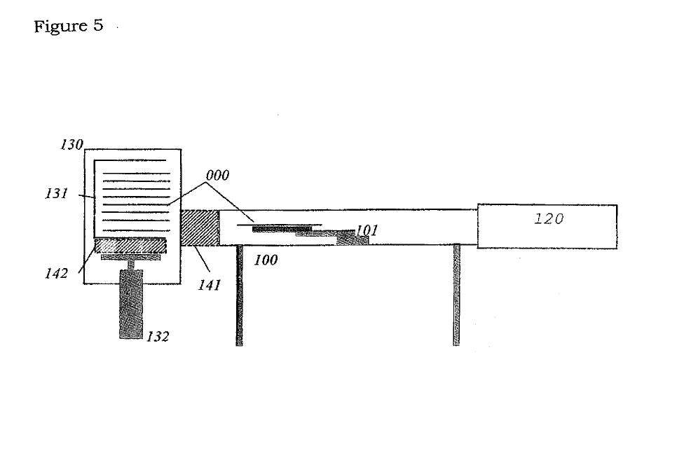

FIG. 5 shows a station arrangement according to the invention in which the adjustment-/cooling station is disposed both in stack construction with the transport container and between transport container and transport chamber.

FIG. 3 shows a station arrangement according to the invention in side view. The station arrangement according to the invention thereby has in principle the same modules as were already illustrated in FIGS. 1 and 2, the same modules are thereby provided with the same reference numbers. However, the arrangement of the adjustment-/cooling station

140 is effected in the manner according to the invention. The station arrangement according to the invention comprises a loading module 130 for a transport container 131, a plurality of semiconductor wafers 000, for example silicon wafers, being mounted in stack construction, in the transport container 131, at deposition places provided for this purpose. Abutting on the loading module 130 for the transport container 131 is a transport chamber (or transport housing) 100 in which a transport robot 101 is disposed. The transport robot 101 is thereby configured such that it can remove a semiconductor wafer 000 from the transport container 131 and can supply it for example to a process station and/or measuring station 120 situated opposite the loading module 130 for the transport container 131.

The basic plan of the station arrangement illustrated in FIG. 3 can thereby be designed in principle precisely as in FIG. 1, i.e. in addition to the process station and/or measuring station 120 illustrated in FIG. 3, also further process stations and/or measuring stations (not illustrated) can be present.

According to the invention, it is now provided that the adjustment-/cooling station 140 is disposed, not as in the state of the art in the interior of the transport chamber 100 or at a place usable for a process module, but is arranged in stack construction below the transport container 131. The stack 131+140 formed from transport container 131 and adjustment-/cooling station 140 is thereby mounted to be vertically adjustable by means of a lift 132 so that a translation can take place with respect to the transport plane of this stack. In the case where now a semiconductor wafer 000 can be supplied for processing, this can be removed from the transport container 131 by means of the robot 101. Subsequently, the stack 131+140 is moved upwards so that the semiconductor wafer 000 can be supplied to the adjustment/-cooling station 140. The trajectory of the path covered by the semiconductor wafer 000, projected onto the transport plane, thereby has the same initial and end point since the semiconductor wafer 000, at the same place as in the original storage position in the transport container 131, adopts a position in the adjustment-/cooling station 140 in projection onto the transport plane.

In the adjustment-/cooling station 140, for example alignment by corresponding rotation or centring of the semiconductor wafer 000 can be effected subsequently on a position provided for this purpose. Subsequently, transfer of the semiconductor wafer 000 by means of the transport robot 101 into the process station and/or measuring station 120 in which a corresponding processing and/or measuring of the semiconductor wafer 000 takes place is effected.

After conclusion of the processing step and/or measuring step, the semiconductor wafer 000 is removed again from the process station and/or measuring station 120 by means of the robot 101 and can be supplied again to the adjustment-/cooling station 140; in this case, for example cooling of the still hot semiconductor wafer 000 coming from the process station and/or measuring station 120 can be effected. The final stowing step in which the semiconductor wafer 000 is removed from the adjustment-/cooling station 140 by means of the robot 101 and is supplied again to the transport container 131 for storage is thereby effected analogously to the removal step from the transport container 131 described initially, i.e. the trajectory of the semiconductor wafer 000 projected onto the transport plane thereby likewise represents a closed path since the initial point, i.e. the position of the semiconductor wafer 000 within the adjustment-/cooling station 140 and the end point, i.e. the mounted position of the semiconductor wafer 000 in the transport container 131, adopt the same position in projection onto the transport plane.

An extremely compact arrangement results herefrom since the adjustment-/cooling station 140 can be disposed below (or above or within) the transport container and hence all sides of the transport chamber 100 are available for process stations. Likewise, it is achieved by the corresponding arrangement of the adjustment-/cooling station 140 that the transport chamber 100 can have smaller dimensions so that it need give sufficient movement clearance, with its dimensions, only for the transport robot.

In principle, it is likewise conceivable, alternatively or additionally to the embodiment illustrated in FIG. 3, to dispose the adjustment-/cooling station 140 below or above a measuring station 120 (or the further measuring stations) and to produce a vertical adjustability of the measuring stations. Likewise vertical adjustability of the robot is conceivable. In this way, removal or supply of the semiconductor wafers from the adjustment-/cooling station 140 into a measuring station 120 is effected analogously on a closed path.

In order to solve the space problem, the adjustment-/cooling stations 140 are hence applied above and/or below the transport container 131. The adjustment-/cooling stations 140 can thereby be part of the transport container 131 or be fitted inside the loading module 130 in a different way. If the transport container 131 is stored statically, then the new position of the adjustment-/cooling stations 140 can be achieved by an extended vertical movement of the transport robot 101. If the transport container 131 is mounted on a vertically moveable lift 132, then the new position of the adjustment-/cooling stations 140 can be achieved by an extended vertical movement of the lift 132.

FIG. 4 illustrates a further embodiment of a station arrangement according to the invention which is based on the same modules as are illustrated in FIGS. 1 to 3. In contrast to the embodiment represented in FIG. 3, the adjustment-/cooling station 140 in the station arrangement 4 is disposed between the loading module 130 and the transport chamber 100.

When removing a semiconductor wafer 000 out of the transport container 131, the robot arm 101 hence grips through the adjustment-/cooling station 140 and removes a corresponding semiconductor wafer 000 from the transport container 131. During transport from the transport container 131 to the process station and/or measuring station 120, the semiconductor wafer 000 hence passes through the adjustment-/cooling station 140 on a direct route (i.e. in this case linearly). According to this arrangement, adjustment of the removed semiconductor wafer can be effected immediately after removal.

Alternatively or also additionally hereto, it is however likewise possible to arrange the adjustment-/cooling station 140 between the transport chamber and a process station and/or measuring station 120 so that for example the supply of the semiconductor wafer 000 from the transport chamber 100 into the process station and/or measuring station 120 can be effected on a direct path. Analogously, the reverse movement directions i.e. transport directions or paths of the semiconductor wafer 000, are likewise direct.

In order to solve the space problem, the adjustment-/cooling station 140 is hence fitted between transport chamber 100 and loading module 130 or a process station and/or measuring station 110, 120. The adjustment-/cooling station 140 is located in the travel region of the transport robot 101. The adjustment-/cooling station 140 can be achieved without further adaptation of the transport robot.

The adjustment-/cooling station 140 can be divided into an adjustment station and a cooling station. The cooling station can be located in the loading module 130, as described in variant a). The adjustment station 140 can be fitted between the transport chamber 100 and the loading module 130 or a process station and/or measuring station 110, 120, as described in variant b).

Likewise, combinations of the embodiments illustrated in FIGS. 3 and 4 are conceivable, for example both an adjustment-/cooling station can be disposed in stack construction according to the embodiments of FIG. 3 and, in addition, at least one further adjustment-/cooling station 140 can be arranged according to the embodiments of FIG. 4, i.e. between loading module 130 and transport chamber 100. The adjustment-/cooling stations 140 can produce respectively only one of the mentioned functions, i.e. either only adjustment or only cooling processes, however, as an alternative hereto, it is likewise possible that the adjustment-/cooling stations comprise both functions.

FIG. 5 describes a further embodiment of a station arrangement according to the invention which is a combination of the module arrangement illustrated in FIGS. 3 and 4. The same reference numbers thereby relate to the same components.

The station arrangement according to FIG. 5 thereby comprises two separate adjustment-/cooling stations 140 and 142, the adjustment-/cooling station 141 being disposed between the transport chamber 100 and the loading module 130. The additional adjustment-/cooling station 142 is thereby mounted statically below the transport container 131.

The first adjustment-/cooling station 141 hence corresponds to the adjustment-/cooling station 140 according to FIG. 4, the second adjustment-/cooling station 142 corresponds to the adjustment-/cooling station 140 according to FIG. 3.

For the function of the adjustment-/cooling station 141 and 142, it can be provided for example that the one adjustment-/cooling station 141 (or 142) has only cooling or tempering function whilst the respectively other adjustment-/cooling station 142 (or 141) is designed merely for undertaking adjustment of a wafer. Likewise, the possibility can be provided however that respectively the adjustment-/cooling station 141 and 142 can undertake both functions, i.e. tempering and spatial alignment, i.e. adjustment of the wafer.

What is claimed is:

1. A station arrangement for processing and/or measuring semiconductor wafers comprising the following modules as minimum components:
a) at least one loading module for storing semiconductor wafers,
b) at least one process station for processing the semiconductor wafers and/or at least one measuring station for measuring the semiconductor wafers,
c) at least one adjustment-/cooling station and
d) at least one transport robot which is disposed in a transport chamber and enables transport of the semiconductor wafers between the at least one loading module, the at least one process station and/or the at least one measuring station and the at least one adjustment-/cooling station,
wherein
the at least one loading module, the at least one process station and/or the at least one measuring station, the at least one adjustment-/cooling station and the transport chamber are disposed spatially relative to each other such that
the projection of the transport path of the semiconductor wafer which is transported by means of the transport robot from the at least one loading module into an adjustment-/cooling station, onto a transport plane, and/or the projection of the transport path of the semiconductor wafer, which is transported by means of the transport robot from an adjustment-/cooling station into the at least one measuring station, onto a transport plane can respectively describe a closed path,
and/or
the projection of the transport path of the semiconductor wafer, which is transported by means of the transport robot from the at least one loading module via an adjustment-/cooling station into the transport chamber, onto a transport plane, and/or the projection of the transport path of the semiconductor wafer, which is transported by means of the transport robot from the transport chamber via an adjustment-/cooling station into the at least one process station and/or the at least one measuring station, onto a transport plane can respectively describe a direct path.

2. The station arrangement according to claim 1, wherein
a) at least one loading module is connected in the transport plane to the transport chamber so that a semiconductor wafer can be transported from the loading module via the connection by means of the transport robot into the transport chamber, or
b) an adjustment-/cooling station is disposed between at least one loading module and the transport chamber connecting the at least one loading module and the transport chamber in the transport direction so that a semiconductor wafer can be transported from the loading module through the adjustment-/cooling station by means of the transport robot into the transport chamber.

3. The station arrangement according to claim 1, wherein
a) the transport chamber is connected in the transport plane to at least one process station and/or at least one measuring station so that a semiconductor wafer can be transported from the transport chamber via the connection by means of the transport robot into the at least one process station and/or into the at least one measuring station, or
b) an adjustment-/cooling station is disposed fitted between the transport chamber and at least one process station connecting the transport chamber and the at least one process station in the transport direction so that a semiconductor wafer can be transported from the transport chamber through the adjustment-/cooling station by means of the transport robot into the at least one process station and/or
c) an adjustment-/cooling station is disposed fitted between the transport chamber and at least one measuring station connecting the transport chamber and the at least one measuring station in the transport direction so that a semiconductor wafer can be transported from the transport chamber through the adjustment-/cooling station by means of the transport robot into the at least one measuring station.

4. The station arrangement according to claim 1, wherein the at least one adjustment-/cooling station is disposed outside the transport chamber.

5. The station arrangement according to claim 1, wherein at least one adjustment-/cooling station together with a loading module or a transport container of a loading module and/or with a measuring station forms a stack which is configured substantially perpendicular or perpendicular to the transport plane.

6. The station arrangement according to claim 5, wherein at least one adjustment-/cooling station together with a loading module or a transport container of a loading module forms a stack, the adjustment-/cooling station being configured at the upper and/or lower end and/or in the interior of the stack.

7. The station arrangement according to claim 1, wherein the station arrangement comprises at least two adjustment-/cooling stations, at least one adjustment/-cooling station together with a process station forming a stack, and this adjustment/-cooling station being configured at the upper and/or lower end of the stack.

8. The station arrangement according to claim 5, wherein the stack is mounted statically and the transport robot comprises a movement component extending perpendicular to the transport plane or the stack is mounted moveably perpendicular to the transport plane.

9. The station arrangement according to claim 1, wherein the at least one loading module, the at least one process station and/or the at least one measuring station, the at least one adjustment-/cooling station and/or the transport chamber are configured respectively to be hermetically sealable from the other modules so that the air pressure can be adjusted respectively differently.

10. A processing method for semiconductor wafers, in which a semiconductor wafer stored in a loading module for storing semiconductor wafers is removed by means of a transport robot, supplied to at least one process station for processing the semiconductor wafers, processed in the at least one process station, subsequently removed from the process station and returned into a loading module,
the semiconductor wafer, after removal from the loading module and before supply into the at least one process station and/or after removal from the at least one process station and before return into a loading module, being transported by means of the transport robot through at least one adjustment-/cooling station and being adjusted there and/or cooled,
wherein
the projection of the transport path of the semiconductor wafer, which is transported by means of the transport robot from the at least one loading module into an adjustment-/cooling station, onto a transport plane, describes a closed path,
and/or
the projection of the transport path of the semiconductor wafer, which is transported by means of the transport robot from the at least one loading module via an adjustment-/cooling station into the transport chamber, onto a transport plane, and/or the projection of the transport path of the semiconductor wafer, which is transported by means of the transport robot from the transport chamber via an adjustment-/cooling station into the at least one process station, onto a transport plane respectively describes a direct path.

11. The processing method according to claim 10, wherein the processing of the semiconductor wafers in the at least one process station comprises tempering, oxidising, sputtering, coating, etching, surface structuring and/or combinations hereof.

12. A measuring method for semiconductor wafers in which a semiconductor wafer stored in a loading module for storing semiconductor wafers is removed by means of a transport robot, supplied to at least one measuring station for measuring at least one measuring variable of the semiconductor wafers, at least one measuring variable of the semiconductor wafers is measured in the at least one measuring station, subsequently the semiconductor wafer is removed from the measuring station and returned into a loading module,
the semiconductor wafer, after removal from the loading module and before supply into the at least one measuring station and/or after removal from the at least one measuring station and before return into a loading module by means of the transport robot, being transported through at least one adjustment-/cooling station and being adjusted there and/or cooled,
wherein
the projection of the transport path of the semiconductor wafer, which is transported by means of the transport robot from at least one loading module into an adjustment-/cooling station, onto a transport plane, and/or the projection of the transport path of the semiconductor wafer, which is transported by means of the transport robot from an adjustment-/cooling station into the at least one measuring station, onto a transport plane describes respectively a closed path,
and/or
the projection of the transport path of the semiconductor wafer, which is transported by means of the transport robot from at least one loading module via an adjustment-/cooling station into the transport chamber, onto a transport plane, and/or the projection of the transport path of the semiconductor wafer, which is transported by means of the transport robot from the transport chamber via an adjustment-/cooling station into the at least one measuring station, onto a transport plan describes respectively a direct path.

13. The measuring method according to claim 12, wherein the surface structuring, the measuring of layer thicknesses, the composition of the semiconductor layers and/or combinations hereof is measured as at least one measuring variable.

14. The processing method according to claim 10, wherein the semiconductor wafers (000)
a) are substantially or completely round, circular or oval, and/or
b) have a maximum dimensioning of at least 100 mm, preferably at least 200 mm, in particular at least 300 mm, particularly preferred at least 450 mm.

15. The processing method according to claim 10, wherein it is implemented with a station arrangement.
